(19) United States
(12) Patent Application Publication
(10) Pub. No.: US 2008/0128813 A1
(43) Pub. Date: Jun. 5, 2008

(54) Semiconductor Device and Manufacturing Method Thereof

(76) Inventors: Ichiro MIZUSHIMA, Yokohama-Shi (JP); Tomoyasu Inoue, Iwaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/947,546

(22) Filed: Nov. 29, 2007

(30) Foreign Application Priority Data
Nov. 30, 2006 (JP) 2006-323880
Nov. 22, 2007 (JP) 2007-303057

(51) Int. Cl. H01L 27/12; H01L 21/84

(52) U.S. Cl. 257/351; 438/154; 257/E21.7; 257/E27.112

(57) ABSTRACT

A semiconductor device includes: a semiconductor substrate; and a plurality of crystalline insulation films which are formed on the semiconductor substrate and have at least two crystalline insulation films. Crystal orientations of the at least two crystalline insulation films are different from each other.

### CROSS REFERENCE TO RELATED APPLICATIONS

This application claims benefit of priority under 35USC §119 to Japanese patent applications No. 2006-323880, filed on Nov. 30, 2006, and No. 2007-303057, filed on Nov. 22, 2007, the contents of which are both incorporated by reference herein.

### BACKGROUND OF THE INVENTION

1. Field of the Invention

The present invention relates to a semiconductor device and a manufacturing method thereof.

2. Related Background Art

In recent years, a semiconductor device with a so-called HOT (hybrid orientation technology) structure has received attention, in which semiconductor crystal layers having different orientations from each other coexist on a principal surface of a common semiconductor substrate.

In order to obtain such a semiconductor device with the HOT structure, a method has been conventionally adopted which includes: bonding semiconductor substrates having different orientations from each other to each other; thinning a semiconductor layer on a surface layer side; locally removing a semiconductor layer on the surface layer side; and growing the semiconductor crystal layer on a region in which the semiconductor layer of a back surface side is exposed.

However, the above described manufacturing method needs two single-crystal layers having different orientations from each other, in order to obtain crystals having the different orientations. Accordingly, the method has needed two wafers in order to prepare one sheet of the semiconductor device with the HOT structure, which has caused increase in a manufacturing cost. In addition, in a step of thinning the wafer, many parts of the wafer in the surface layer side are wasted, which has needed many steps and consequently a long period of time for manufacturing the semiconductor device, so that the method has been strongly demanded for improvement both in terms of cost and period.

### SUMMARY OF THE INVENTION

According to a first aspect of the present invention, there is provided a semiconductor device comprising:

a semiconductor substrate; and

a plurality of crystalline insulation films including at least two crystalline insulation films which are formed on the semiconductor substrate, respectively, and have different crystal orientations from each other.

According to a second aspect of the present invention, there is provided a method of manufacturing a semiconductor device comprising

forming a crystalline insulation film on the semiconductor substrate, while locally irradiating the semiconductor substrate with energy rays.

### BRIEF DESCRIPTION OF THE DRAWINGS

FIG. 1 is a sectional view schematically illustrating a structure of a semiconductor device according to a first embodiment of the present invention;

FIGS. 2 and 3 are sectional views for describing a method of manufacturing a semiconductor device illustrated in FIG. 1;

FIG. 4 is a sectional view for describing a method of manufacturing a semiconductor device illustrated in FIG. 1;

FIG. 5 is a view for describing a growing process of crystals in a manufacturing step illustrated in FIG. 4;

FIGS. 6A and 6B are views for describing a change of a crystal orientation of a crystalline insulation film due to irradiation with energy rays;

FIG. 7 is a view for describing a relationship between three-dimensional crystal directions when both of cerium oxide (CeO2) having the orientation of the (100) face and cerium oxide (CeO2) having the orientation of the (110) face concurrently grow on a semiconductor single crystal commonly having the orientation of the (100) face;

FIG. 8 is a cross sectional view for describing a method of manufacturing a semiconductor device having an HOT structure with a conventional technology;

FIGS. 9 through 11 are cross sectional views for describing a method of manufacturing a semiconductor device having an HOT structure with a conventional technology;

FIG. 12 is a cross sectional view schematically illustrating a structure of a semiconductor device according to a second embodiment of the present invention;

FIG. 13 is a cross sectional view illustrating an example of an LSI produced by using a semiconductor device illustrated in FIG. 12;

FIG. 14 is a sectional view schematically illustrating a structure of a semiconductor device according to a third embodiment of the present invention;

FIG. 15 is a graph illustrating a relationship between an off-angle of crystal axis ((100) axis) of a silicon single crystal directing at the <100> direction from the normalized minimum ion yield;

FIG. 16 is a cross sectional view schematically illustrating a structure of a semiconductor device according to a fourth embodiment of the present invention; and

FIG. 17 is a cross sectional view illustrating an example of an LSI produced by using a semiconductor device illustrated in FIG. 16.

### DETAILED DESCRIPTION OF THE INVENTION

Some of embodiments according to the present invention will now be described with reference to the drawings. In each drawing illustrated below, the same reference number will be used for designating the same portion, and repeated explanation thereof will be appropriately omitted. In addition, when a double underline is drawn under a numeric in parentheses representing a crystal orientation, the double underline originally indicates a top bar as is clear from the description in a corresponding drawing, and it is to be noted that the double underline is used as a substitute due to restricted expression.

### (1) First Embodiment

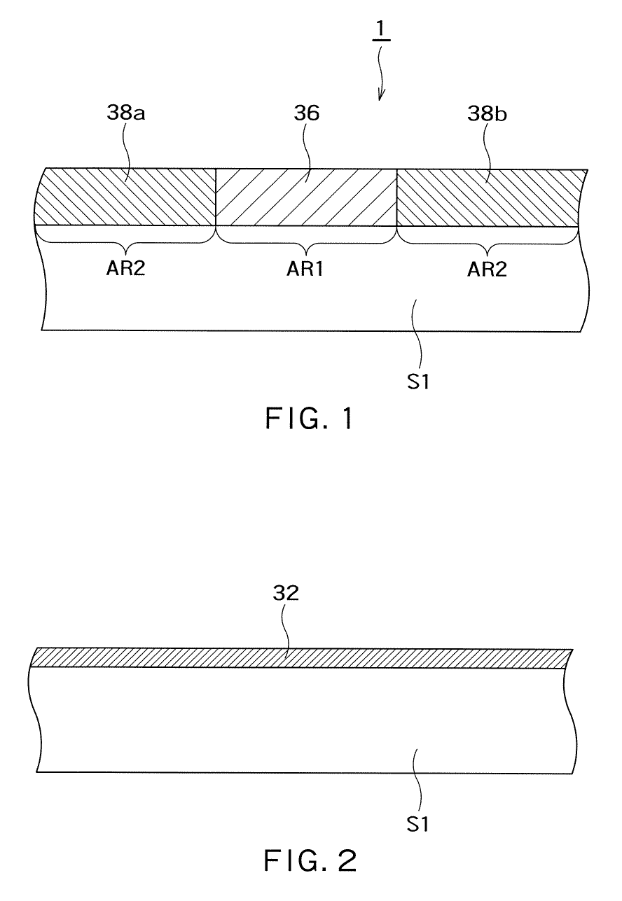

A first embodiment according to the present invention will now be described with reference to FIGS. 1 to 11.

FIG. 1 is a sectional view schematically illustrating a structure of a semiconductor device according to a first embodiment of the present invention. A semiconductor device 1 illustrated in FIG. 1 comprises: a silicon single-crystal substrate S1 having the orientation of the (100) face; a cerium oxide (CeO₂) film 36 formed on a part of the region AR1 of the principal surface of the substrate S1; and cerium oxide (CeO₂) films 38a and 38b formed on the other region AR2 on the principal surface of the substrate S1. The cerium oxide (CeO₂) film 36 and the cerium oxide (CeO₂) films 38a and 38b correspond to, for instance, two crystalline insulation films in the present embodiment, and have different crystal orientations from each other. More specifically, the cerium oxide (CeO₂) film 36 has the orientation of the (100) face, and the cerium oxide (CeO₂) films 38a and 38b have the orientation of the (110) face.

Thus, the semiconductor device according to the present embodiment has an HOT structure in which the crystalline insulation films having a plurality of different crystal orientations are formed on a common semiconductor substrate. Thereby, an LSI having excellent characteristics can be produced, for instance, by forming elements showing excellent characteristics in respective orientations on crystalline regions having respective orientations, as will be described later in a second embodiment.

A method of manufacturing a semiconductor device illustrated in FIG. 1 will now be described with reference to FIGS. 2 to 7.

At first, a cerium (Ce) film 32 is formed on a silicon single-crystal substrate S1 having the orientation of the (100) face into a thickness of about 1.5 nm, by depositing cerium (Ce) with a sputtering technique, as is illustrated in FIG. 2.

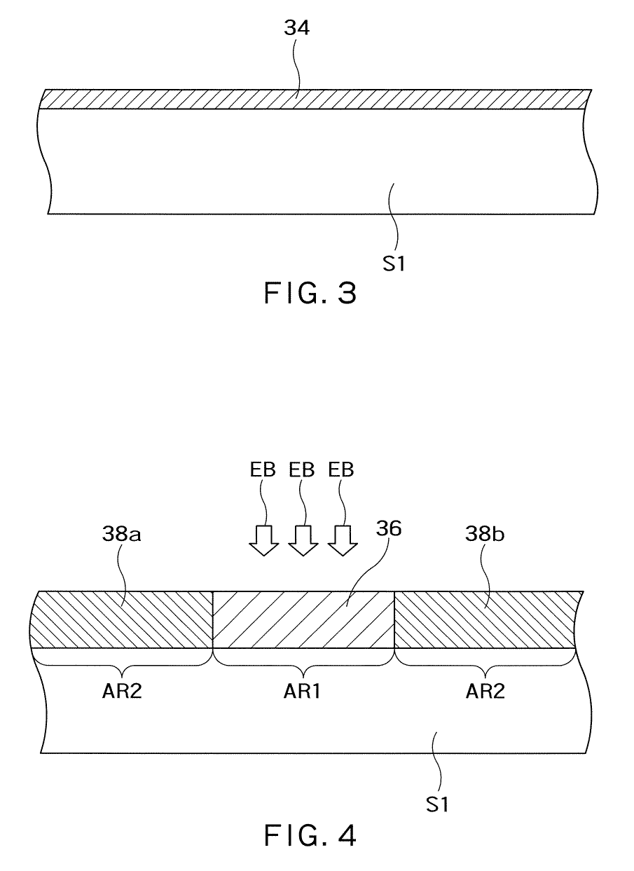

Subsequently, the substrate Si is heat-treated at 400° C. in a vacuum for 30 seconds, as is illustrated in FIG. 3. Thereby, the cerium (Ce) film 32 formed on the substrate S1 is converted into cerium silicide (CeSi₂) 34.

Next, cerium oxide (CeO₂) is deposited into a thickness of 50 nm on the cerium silicide (CeSi₂) 34 with part of the substrate in the region AR1 being alone irradiated with energy rays, as is illustrated in FIG. 4. The energy rays employed in the present embodiment is an electron beam EB of 90 eV. In addition, a reactive sputtering technique is used in the present embodiment, which deposits cerium oxide (CeO₂) on the substrate S1 by sputtering Ce in a mixture gas atmosphere of Ar/O₂ while keeping the temperature of the substrate S1 at 800° C. As a result of having confirmed the crystal orientation of the deposited cerium oxide (CeO₂) with an electron beam diffraction technique, it was confirmed that cerium oxide (CeO₂) having the orientation of the (100) face was epitaxially grown in the region AR1 which had been irradiated with the electron beam, and that cerium oxide (CeO₂) having the orientation of the (110) face was epitaxially grown in the region AR2 which had not been irradiated with the electron beam. Incidentally, it was revealed that cerium silicide (CeSi₂) which had existed on the surface of the substrate S1 before the step of forming the cerium oxide (CeO₂) film was vanished because cerium (Ce) rediffused into the cerium oxide (CeO₂) film and silicon (Si) rediffused into a silicon (Si) substrate S1 after the cerium oxide (CeO₂) films 36, 38a and 38b had been formed, and that a structure was formed in which cerium oxide (CeO₂) was formed right on the silicon (Si) substrate S1 having the orientation of the (100) face.

Here, the reason of forming cerium silicide (CeSi₂) 34 before growing cerium oxide (CeO₂) will now be described. Specifically, assume that the cerium oxide (CeO₂) film is formed right on the silicon (Si) substrate without forming cerium silicide (CeSi₂) 34. Then, a thermal oxide film SiO₂ is formed on the whole surface of the silicon (Si) substrate Si, because cerium oxide (CeO₂) is grown in an oxidative atmosphere and consequently the surface of the silicon (Si) substrate S1 is oxidized before the whole surface is coated with cerium oxide (CeO₂). The thermal oxide film SiO₂ is not crystalline but is amorphous, so that even though subsequent growth of cerium oxide (CeO₂) on the substrate S1 is attempted, the film cannot succeed crystallinity forming the silicon (Si) substrate S1 which is an underlayer. For this reason, when cerium oxide (CeO₂) is once formed on the silicon (Si) surface, the oxidation of silicon (Si) surface can be inhibited from oxidizing. Thereby, cerium oxide (CeO₂) succeeds crystallinity of cerium silicide (CeSi₂) 34 and can grow in a single-crystal form.

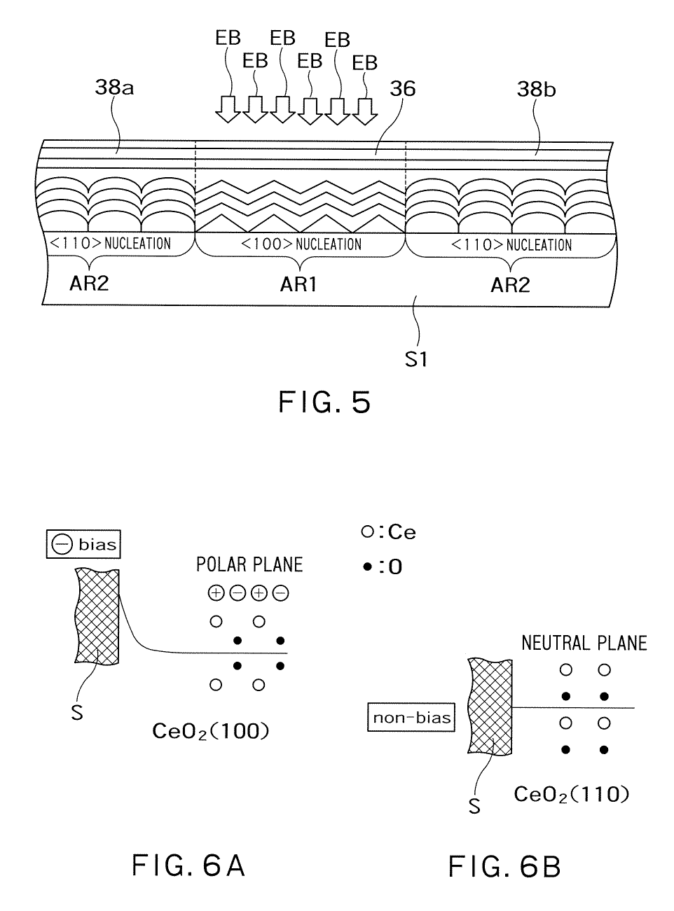

The growing process of crystals was examined by observing the cross section of cerium oxide (CeO₂) having grown in a single-crystal form by use of a transmission electron microscope, in order to examine a mechanism through which cerium oxide (CeO₂) films 36, 38a and 38b are formed into crystals having different orientations from each other while depending on the presence or absence of irradiation with an electron beam. As a result, the following fact was found: the orientation of a crystal nucleus of cerium oxide (CeO₂) formed right on a substrate S1 changes depending on whether the region is irradiated with the electron beam EB or not; the crystal nuclei of cerium oxide (CeO₂) having each orientation are combined with each other in each region; and a cerium oxide (CeO₂) film 36 having the orientation of the (100) face is formed on an region AR1 which has been irradiated with the electron beam EB, and cerium oxide (CeO₂) films 38a and 38b having the orientation of the (110) face are formed on an region AR2 which has not been irradiated with the electron beam EB, as are illustrated in an explanatory drawing of FIG. 5.

The reason why the orientation of a crystal nucleus of cerium oxide (CeO₂) formed right on a substrate S1 changes depending on whether the region is irradiated with an electron beam EB or not is considered that because the crystal of cerium oxide (CeO₂) has different electric anisotropy according to the orientation of the crystal face, and accordingly acquires different orientations toward which crystals can stably grow, between crystals growing on regions AR1 and AR2, when different surface potentials are locally given to the crystals by the irradiation with the electron beam EB. The conceptual diagram is illustrated in FIGS. 6A and 6B. Cerium oxide (CeO₂) has electric polarity in the direction to the (100) face, but has no polarity in the direction to the (110) face. As a result of this, cerium oxide (CeO₂) having the direction of the (100) face is considered to have grown only in the region AR1 having a changed surface potential by the irradiation with the electron beam, as is illustrated in FIG. 6A. In contrast to this, single crystals having the (110) orientation are considered to have grown on the surface of the region AR2 that has not been irradiated with the electron beam EB because the surface of the region AR2 is electrically neutral and gives the (110) orientation that is a direction having no electric anisotropy among many orientations to the crystal of cerium oxide (CeO₂), as is illustrated in FIG. 6B.

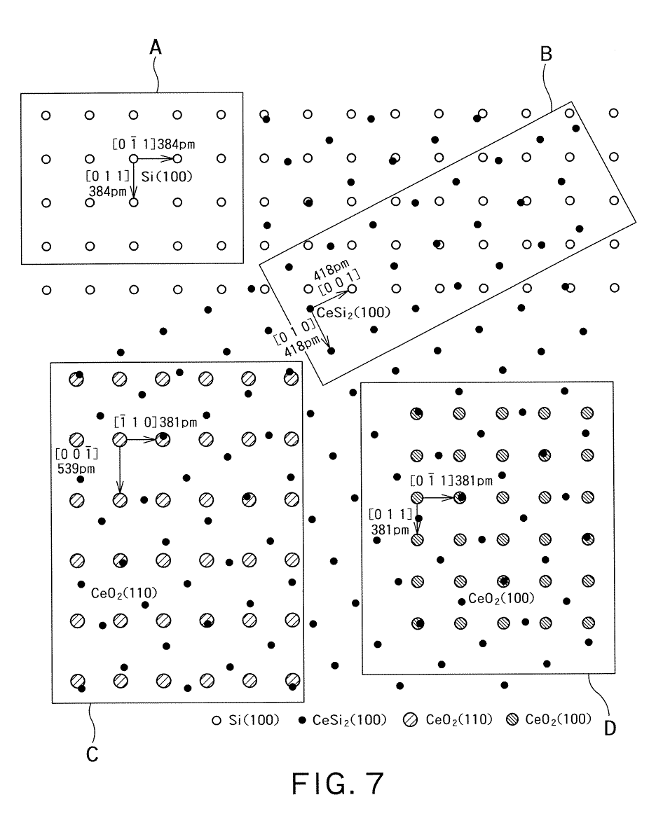

A relationship between different three-dimensional crystal directions will now be described with reference to FIG. 7, which occurs when both cerium oxide (CeO₂) having the orientation of the (100) face and cerium oxide (CeO₂) having the orientation of the (110) face simultaneously grow on a silicon (Si) single crystal commonly having the orientation of the (100) face, as described above. Incidentally, such a relationship between crystal directions is described in an article written by R. L. Goettler, J. P. Maria and D. G. Schlom, in Mat. Res. Soc. Symp. Proc. vol. 474, p. 333 (1997).

A region (A) in an upper-left corner of FIG. 7 illustrates a position of silicon (Si) crystals in which the orientation of the (100) face is assumed to direct at a direction perpendicular to the surface of the paper. In the silicon (Si) crystal, a direction of [0 1 1] and a direction of [0 1 1] are mutually perpendicular and each of them is perpendicular to a direction of [100]. A region (B) in an upper-right corner of FIG. 7 illustrates an array of crystals of cerium silicide (CeSi₂) when the crystals of cerium silicide (CeSi₂) are epitaxially grown on the silicon (Si) crystal. Cerium silicide (CeSi₂) is epitaxially grown so that the direction of [0 3 1] of an underlayer silicon (Si) single crystal almost matches to the direction of [0 0 1] of cerium silicide (CeSi₂), and the direction of [0 1 3] of the underlayer silicon (Si) single crystal almost matches to the direction of [0 1 0] of CeSi₂.

When cerium oxides (CeO₂) is further epitaxially grown on cerium silicide (CeSi₂) which has grown as described above, the crystal of cerium oxide (CeO₂) having grown on a region which is irradiated with an electron beam shows a different crystal orientation from the crystal of cerium oxide (CeO₂) having grown on a region which is not irradiated with the electron beam. In the region which has not been irradiated with the electron beam, cerium oxide (CeO₂) having the orientation of the (110) face grows as is illustrated in a region (C) in a lower-left part of FIG. 7. The cerium oxide (CeO₂) grows so that the direction of [0 1 1] of an underlayer silicon (Si) matches to the direction of [1 1 0] of cerium oxide (CeO₂), and the direction of [0 1 1] of the underlayer silicon (Si) matches to the direction of [0 0 1] of cerium oxide (CeO₂). In contrast to this, in the region which has been irradiated with the electron beam, cerium oxide (CeO₂) having the orientation of the (100) face grows as in a region (D) of a lower-right corner of FIG. 7. The cerium oxide (CeO₂) grows so that the direction of [0 1 1] of the underlayer silicon (Si) matches to the direction of [0 1 1] of cerium oxide (CeO₂), and the direction of [0 1 1] of the underlayer silicon (Si) matches to the direction of [0 1 1] of cerium oxide (CeO₂).

In all regions in which crystals having either face orientation have grown as described above, the formed cerium oxide (CeO₂) film have suitable crystalline quality. This is because a lattice spacing of (100) face of a silicon (Si) crystal in the direction of [0 1 1] (384 μm) is very close to a lattice spacing in the (110) face and the (100) face of a cerium oxide (CeO₂) crystal in the direction of [1 1 0] (or [0 1 1]) (381 μm).

As described above, a semiconductor device according to the present embodiment can have crystalline insulation films having different face orientations formed on a common silicon (Si) substrate, and can be applied to wide fields. For instance, the semiconductor device can form regions having different optical properties formed at an arbitrary position on a semiconductor substrate.

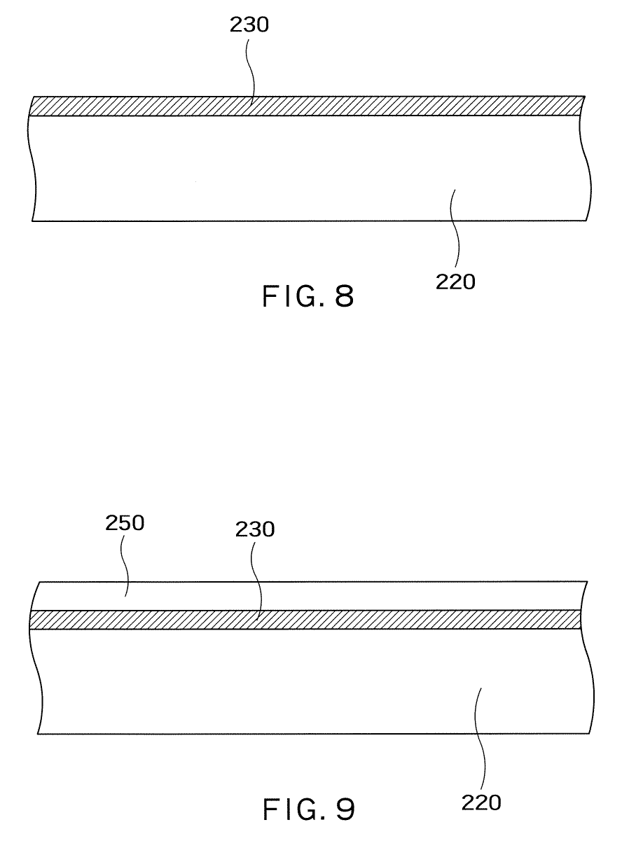

A method of manufacturing a semiconductor device with an HOT structure with a conventional technology will now be described as a comparative example of a method of manufacturing a semiconductor device according to the present embodiment, with reference to FIGS. 8 to 11.

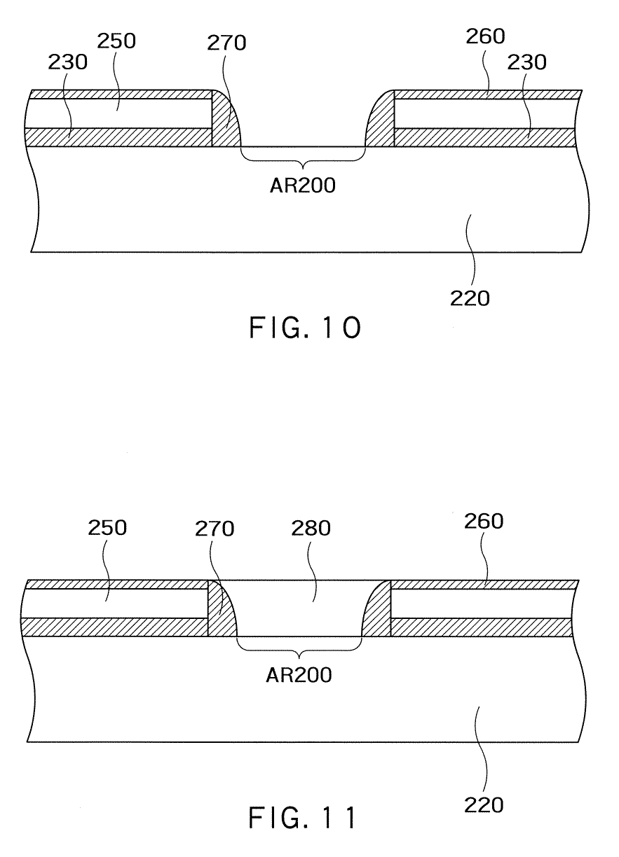

At first, a thermal oxide film 230 with a thickness of 30 nm is formed on a silicon (Si) substrate 220 having the orientation of the (100) face, as is illustrated in FIG. 8. Next, a structure illustrated in FIG. 9 is prepared by sticking a silicon (Si) substrate 250 having the orientation of the (110) face to the surface of the thermal oxide film 230, and thinning the silicon (Si) substrate 250 from the opposite side of the stuck face to the substrate 220. Subsequently, a structure illustrated in FIG. 10 is prepared by depositing a silicon oxide film 260 on the silicon (Si) layer 250; patterning the silicon oxide film 260 with a mask (not shown); then selectively removing the silicon oxide film 260, the silicon (Si) layer 250, and a silicon oxide layer 230 with an etching technique; and forming a side wall 270 of the silicon oxide film with a known method. Subsequently, a silicon (Si) layer 280 is selectively grown only on a region AR 200 in which silicon (Si) is exposed, with a so-called selective growing method, as is illustrated in FIG. 11. Thereby, an HOT structure can be formed on the principal surface of the silicon (Si) substrate 220, which consists of a silicon (Si) single crystal (280) having the orientation of the (100) face and a silicon (Si) single crystal (250) having the orientation of the (110) face.

However, a method by a conventional technology needs two sheets of single-crystal layers having different orientations in order to obtain crystals having different orientations. In other words, two wafers are necessary for producing one sheet of a semiconductor device having an HOT structure as described above. Accordingly, a conventional technology has been strongly demanded for improvement both in terms of cost and term (period).

A manufacturing method according to the present embodiment can form plural kinds of regions of semiconductor crystals on a common single substrate without using a mask through a simple process, each region having different face orientations.

Incidentally, the semiconductor device illustrated in FIG. 11 has an SOI structure only in a region having the orientation of the (110) face, and shows a bulk form having no oxide layer buried as the underlayer, in a region having the orientation of the (100) face. But, it is possible to form SOI forms in both of the region having the orientation of the (110) face and the region having the orientation of the (100) face, or to form the bulk forms in both of the regions, by using a known method.

### (2) Second Embodiment

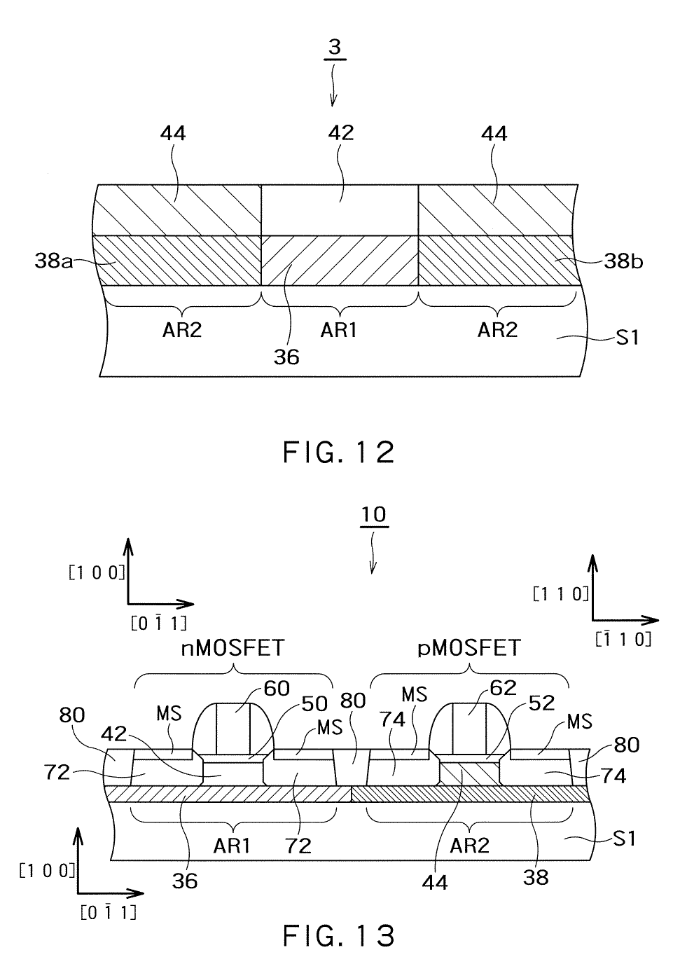

In the next place, a second embodiment according to the present invention will be described with reference to FIG. 12 and FIG. 13.

FIG. 12 is a cross sectional view schematically illustrating a structure of a semiconductor device 3 according to the present embodiment. The semiconductor device 3 illustrated in FIG. 12 further comprises silicon single-crystal layers 42 and 44 formed on the semiconductor device 1 illustrated in FIG. 1. The silicon single-crystal layers 42 and 44 are formed on cerium oxide (CeO₂) 36, 38a and 38b respectively so as to succeed the crystal orientation of the underlayer, and accordingly have the orientation of the (100) face and the orientation of the (110) face, respectively.

It is known that an element prepared by forming, for instance, an MOSFET on the semiconductor device 3 illustrated in FIG. 12 shows the same characteristics as in the case of an element prepared by forming the MOSFET on a semiconductor device prepared by forming crystals having the orientation of the (100) face and crystals having the orientation of the (110) face on the same substrate with a conventional method, when both characteristics are evaluated.

A method of manufacturing a semiconductor device 3 according to the present embodiment will now be described below.

Specifically, a silicon single-crystal layer is formed on a semiconductor device 1 prepared in the first embodiment, into a thickness of 50 nm with a CVD technique. Here, silicon (Si) is deposited on the semiconductor device 1 at 800° C. with the CVD technique by using dichlorosilane as a source gas. A silicon (Si) single crystal formed on a cerium oxide (CeO₂) film 36 having the orientation of the (100) face is epitaxially grown so as to acquire the orientation of the (100) face, and a silicon (Si) single crystal formed on cerium oxide (CeO₂) films 38a and 38b having the orientation of the (110) face is epitaxially grown so as to acquire the orientation of the (110) face. Accordingly, as for the silicon single-crystal layer, a silicon (Si) layer 42 acquires the orientation of the (100) face and a silicon (Si) layer 44 acquires the orientation of the (110) face, as are illustrated in FIG. 12.

Thus formed silicon (Si) layer 42 having the orientation of the (100) face and the silicon (Si) layer 44 having the orientation of the (110) face have the same relationship between the crystal orientations as in the case of cerium oxide (CeO₂) illustrated in FIG. 7. In other words, the silicon (Si) layers grow so that the direction of [0 1 1] in silicon (Si) having the orientation of the (100) face is parallel to the direction of [1 1 0] of silicon (Si) having the orientation of the (110) face, and the direction of [0 1 1] in silicon (Si) having the orientation of the (100) face is parallel to the direction of [0 0 1] in silicon (Si) having the orientation of the (110) face.

Here, in an nMOSFET formed on a silicon (Si) substrate, it is known that the maximum mobility is obtained when an electric current flows in the direction of [0 1 1] with the use of a substrate having the orientation of the (100) face. In contrast to this, in a pMOSFET, it is known that the maximum mobility is obtained when an electric current flows in the direction of [1 1 0] with the use of a substrate having the orientation of the (110) face. Accordingly, when an LSI having the nMOSFET combined with the pMOSFET is produced on an HOT structure of a semiconductor device 3 so that an electric current flows in the direction of [0 1 1] and the direction of [1 1 0], the respective MOSFETs can show their best characteristics, and as a result, thus obtained LSI can show the best characteristics.

FIG. 13 is a partial sectional view illustrating an example of an LSI having an nMOSFET and a pMOSFET formed on a semiconductor device having an HOT structure illustrated in FIG. 12.

A semiconductor device 10 illustrated in FIG. 13 is obtained by manufacturing a semiconductor device 3 illustrated in FIG. 12, and subsequently forming an device-isolating insulation film 80, gate insulation films 50 and 52, polysilicon electrodes 60 and 62, impurity diffusion layers 72 and 74 and a silicide layer MS, by using a known method. The semiconductor device 30 comprises an nMOSFET formed on a region AR1 in which a silicon (Si) layer 42 having the orientation of the (100) face is formed, and a pMOSFET formed on a region AR2 in which a silicon (Si) layer 44 having the orientation of the (110) face is formed. As is illustrated by arrows in FIG. 13, the direction of an electric current flowing through the channel in the nMOSFET side is the direction of [0 1 1], and on the other hand, the direction of an electric current flowing through the channel in the pMOSFET is the direction of [1 1 0]. As a result, high mobility could be obtained in any MOSFET.

### (3) Third Embodiment

It is found that when cerium oxide (CeO₂) films 38a and 38B having the orientation of the (110) face are formed on regions AR2 which grow an Si thin film 44 having the orientation of the (110) face on an Si substrate S1 having the orientation of the (100) face, for instance, in FIG. 12, according to the manufacturing method in the above described embodiment, each of films 38a and 38b is occasionally formed so as to be inclined by 90 degrees relative to each other. In such a case, elements formed thereon result in acquiring different characteristics from each other. The present embodiment provides a semiconductor device having no variation of such a rotation angle.

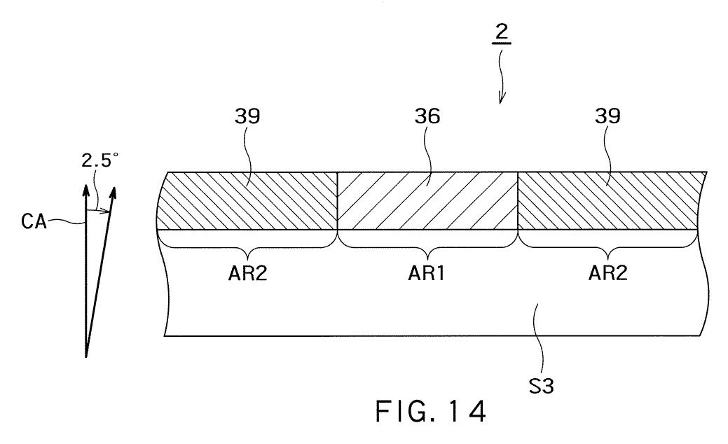

A semiconductor device 2 illustrated in FIG. 14 comprises a silicon single-crystal substrate S3 having the orientation of the (100) face, a cerium oxide (CeO₂) film 36 formed on a region AR1 which is a part of the principal surface of the substrate S3, and a cerium oxide (CeO₂) film 39 formed on another region AR2 on the principal surface of the substrate S3. The cerium oxide (CeO₂) film 36 and the cerium oxide (CeO₂) film 39 correspond to, for instance, two crystalline insulation films in the present embodiment. The semiconductor device 2 according to the present embodiment is characterized in that it is formed of silicon single crystals which are set so that the crystal axis ((100) axis) thereof directing at the direction of <110> has a predetermined angle (an off-angle) from the normal line of the substrate S3 in the direction of [0 0 1].

As a result of having grown a cerium oxide (CeO₂) film on the underlayer substrate S3 set as described above with the same method as in the first embodiment, the cerium oxide (CeO₂) film having the orientation of the (110) face, which has grown on an region AR2, showed a greatly different growth state from that in the first embodiment. Specifically, in the first embodiment, the grown cerium oxide (CeO₂) film having the orientation of the (110) face occasionally shows two types of rotation angles which are inclined by 90 degrees relative to each other. However, it was revealed that cerium oxide (CeO₂) films 39 having the orientation of the (110) face were formed in a single crystal structure on the underlayer substrate S3 without causing any variation of rotation angles with respect to each other since the crystal axis ((100) axis) of the silicon single crystals which form the underlayer substrate S3 and direct at the direction of <100> has a predetermined angle (an off-angle) from the normal line of the substrate S3 in the direction of [0 0 1] according to the present embodiment. Thereby, an element formed on the cerium oxide (CeO₂) film 39 can show its inherent characteristics of the element formed on the crystal having the orientation of the (110) face.

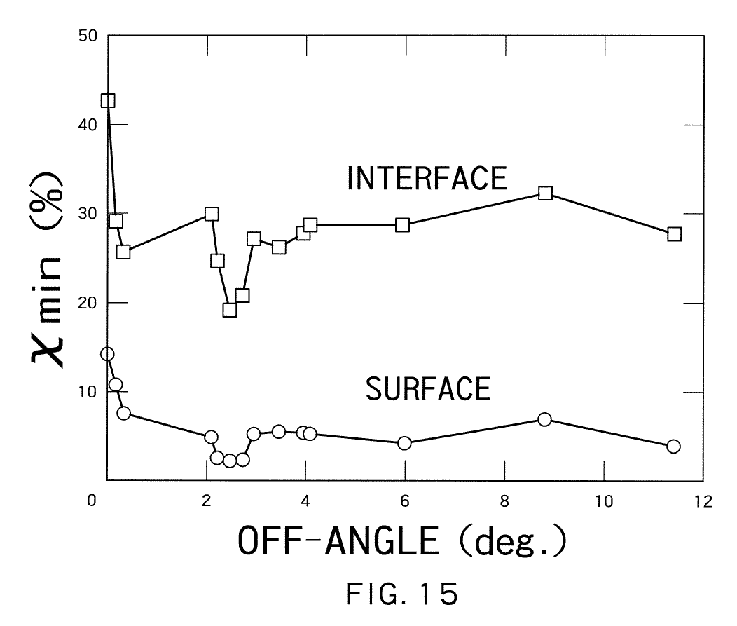

The off-angle of the crystal axis ((100) axis) of the silicon single crystals directing at the direction of <100> from the normal line of the substrate S3 has only to be 0.5 degrees to 7 degrees, as is illustrated in FIG. 15, but it is known that the best characteristics are obtained when the off-angle of 2.5 degrees is adopted. In FIG. 15, “X min” represents the normalized minimum ion yield which means the ratio of the back-scattered ion yield under axis channeling condition and the back-scattered ion yield under non-channeling condition. (The smaller the normalized minimum ion yield is, the better the characteristics of the crystal is.) As is understood from FIG. 15, when the off-angle is 0.5 degrees or larger, an obtained semiconductor device shows the same single domain structure as in the semiconductor device 2 to be obtained in the present embodiment, and when the off-angle is 7 degrees or smaller, the obtained semiconductor device shows electric characteristics which are not much inferior to electric characteristics to be obtained from that formed on the original cerium oxide (CeO₂) film having the orientation of the (100) face or the (110) face.

Thus, two different domains which would be shown on a substrate formed of semiconductor crystal with no off-angle are not observed in the case of a substrate is adopted which is formed of semiconductor crystal with such off-angle agrees. This result resembles the result which would be caused in the case of CeO₂ grown without being irradiated with an electron beam (for instance, Mat. Res. Symp. Proc. Vol. 341, 1994, materials Research Society, p. 101, T. Inoue et al., Study of Epitaxial Growth of CeO₂ (110)/(100) in Conjunction with Substrate Off-Orientation). The result obtained in the present embodiment is considered to be based on the same mechanism as shown in the above described literature.

### (4) Fourth Embodiment

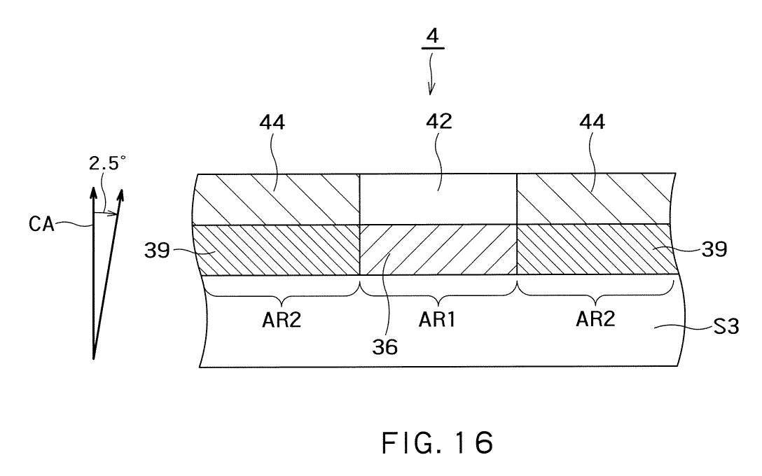

FIG. 16 is a cross sectional view schematically illustrating a structure of a semiconductor device 4 according to the present embodiment. The semiconductor device 4 illustrated in FIG. 16 further comprises silicon single-crystal layers 42 and 44 formed on a semiconductor device 2 illustrated in FIG. 14, as in the case of a semiconductor device 3 illustrated in FIG. 12. The silicon single-crystal layers 42 and 44 are formed on cerium oxides (CeO₂) 36 and 39 respectively, succeed the crystal orientation of the lower layer, and have the orientation of the (100) face and the orientation of the (110) face respectively.

A method of manufacturing a semiconductor device 4 according to the present embodiment is similar to that in the above described third embodiment, except that the present embodiment employs a substrate S3 formed of the silicon single crystals which direct at the direction of <100> and whose crystal axis ((100) axis) has an off-angle of 2.5 degrees from the normal line CA of the underlayer substrate S3.

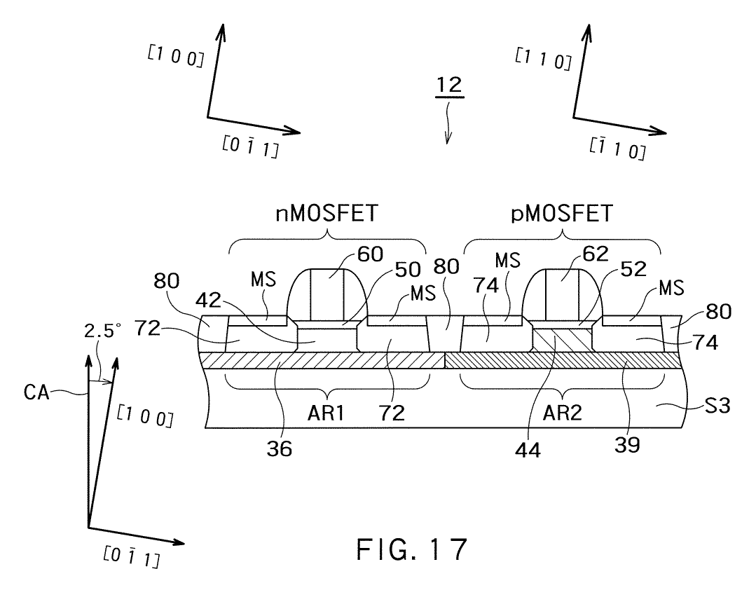

FIG. 17 is a partial sectional view illustrating an example of an LSI having an nMOSFET and a pMOSFET formed on a semiconductor device 4 having an HOT structure illustrated in FIG. 16.

A semiconductor device 12 illustrated in FIG. 17 is obtained by manufacturing the semiconductor device 4 illustrated in FIG. 16, and subsequently forming an device-isolating insulation film 80, gate insulation films 50 and 52, polysilicon electrodes 60 and 62 formed as gate electrodes, impurity diffusion layers 72 and 74 and a silicide layer MS, by using a known method. The semiconductor device 12 comprises an nMOSFET formed on a region AR1 in which a silicon (Si) layer 42 having the orientation of the (100) face is formed, and a pMOSFET formed on a region AR2 in which a silicon (Si) layer 44 having the orientation of the (110) face is formed. As is illustrated by arrows in FIG. 17, the direction of an electric current flowing through the channel in the nMOSFET side is the direction of [1 1 0], which is inclined by 2.5 degrees relative to the nominal line CA of the underlayer substrate S3, and the direction of an electric current flowing through the channel in the pMOSFET is the direction of [1 1 0], which is inclined 2.5 degrees relative to the nominal line CA of the underlayer substrate S3. As a result, high mobility could be obtained in any MOSFET. Furthermore, a device according to the present embodiment can show original characteristics to a device prepared by using silicon crystals having the orientation of the (110) face, because the rotation angle of cerium oxides (CeO₂) 39 is consistent in any pMOSFET.

Some embodiments of the present invention have been described above, but the present invention is not limited to the above described embodiments. It is natural that the embodiments can be variously modified within the scope of the invention.

For instance, a sputtering technique is employed as a method of forming a film of cerium (Ce) or cerium oxide (CeO₂) in the above described embodiments, but the method is not limited to the sputtering technique. A vacuum deposition technique, an MBE (Molecular Beam Epitaxy) technique, a CVD (Chemical Vapour Deposition) technique or a laser ablation technique may be used, for instance.

In addition, the energy of an electron beam is set at 90 eV in the above described embodiments, but is not limited thereto, and may be any voltage in a range of several eV and 1 keV. In addition, a method of irradiating a part of a region in a substrate with the electron beam is not only a method of scanning the electron beam, but also may be a method of moving a stage which supports the substrate. Furthermore, a mask with an opening only in a region to be irradiated can be used.

Furthermore, a method of irradiating only a part of a region with an electron beam is employed for varying an electric potential of the part so as to simultaneously form cerium oxides (CeO₂) having different crystal orientations, as is shown in the first embodiment. However, a method of irradiating the part with a beam of ions of hydrogen, helium or the like of a charged particle beam may be used, and besides, X-rays or ultraviolet rays may be used.

In addition, in the above described embodiments, an example of cerium oxide (CeO₂) is shown as a crystalline insulator but the crystalline insulator is not limited to cerium oxide, and may be any oxide as long as it has a composition formula expressed by CeₓO_{y} (1.5≦(y/x)≦2). Furthermore, even a crystalline insulator containing crystals having electrical polarity and having no electrical polarity depending on the orientation of the crystal face, for instance, such as magnesium oxide (MgO), spinel (MgAl₂O₄), barium oxide (BaO), aluminum oxide (Al₂O₃) and yttrium oxide (Y₂O₃) can show the same effect as in the present invention.

In addition, a silicon (Si) substrate is used as a semiconductor substrate in any of the above described embodiments, but the semiconductor substrate is not limited to the silicon (Si) substrate, and may be one formed of, for instance, a semiconductor such as germanium (Ge), silicon carbide (SiC) and gallium arsenide (GaAs), or a semiconductor of mixed crystals such as silicon germanium (SiGe).

What is claimed is:

1. A semiconductor device comprising:
a semiconductor substrate; and
a plurality of crystalline insulation films including at least two crystalline insulation films which are formed on the semiconductor substrate, respectively, and have different crystal orientations from each other.

2. The semiconductor device according to claim 1, further comprising
semiconductor crystal layers which are formed on the crystalline insulation films, respectively, and have the same crystal orientation as in the crystalline insulation film underlying the semiconductor crystal layers, respectively.

3. The semiconductor device according to claim 1,
wherein the crystalline insulation film is an insulator containing crystals having electrical polarity and crystals having no electrical polarity depending on the respective orientations of the crystal faces.

4. The semiconductor device according to claim 1,
wherein the crystalline insulation film includes an oxide expressed by the composition formula CeₓO_{y} (1.5≦(y/x)≦2).

5. The semiconductor device according to claim 1,
wherein the semiconductor substrate is formed from a semiconductor including any one of silicon (Si), germanium (Ge), silicon carbide (SiC) and gallium arsenide (GaAs), or a semiconductor of a mixed crystal including silicon germanium (SiGe).

6. The semiconductor device according to claim 1,
wherein the substrate is formed of semiconductor crystals each of which has an orientation of the (100) face and each crystal axis of which has an off-angle of 0.5 degrees to 7 degrees relative to a nominal line of the substrate.

7. The semiconductor device according to claim 2, further comprising a MISFET including a gate insulating film formed on the semiconductor crystal layer, a gate electrode formed on the gate insulating film and an impurity diffusion layer formed in the semiconductor crystal layer.

8. The semiconductor device according to claim 14,
wherein a MISFET of a first conductivity type and a MISFET of a second conductivity type different from the first conductivity type are formed on the semiconductor crystal layers having different crystal orientations from each other, respectively.

9. A method of manufacturing a semiconductor device comprising
forming a crystalline insulation film on the semiconductor substrate, while locally irradiating the semiconductor substrate with energy rays.

10. The method of manufacturing the semiconductor device according to claim 9, further comprising forming a semiconductor single-crystal layer on the formed crystalline insulation film.

11. The method of manufacturing the semiconductor device according to claim 9, further comprising
forming a metallic silicide on the substrate before forming the crystalline insulation film.

12. The method of manufacturing the semiconductor device according to claim 9,
wherein the energy rays include any one of a charged particle beam, an X-ray and an ultraviolet ray.

13. The method of manufacturing the semiconductor device according to claim 9,
wherein the substrate is formed of semiconductor crystals each of which has an orientation of the (100) face and each crystal axis of which has an off-angle of 0.5 degrees to 7 degrees relative to a nominal line of the substrate.

14. The method of manufacturing a semiconductor device according to claim 9, further comprising forming semiconductor crystal layers on the crystalline insulation film so as to have different crystal orientations from each other in response to crystal orientations in the crystalline insulation film underlying the semiconductor crystal layers, depending on presence or absence of irradiation with the energy rays, respectively.

15. The method of manufacturing a semiconductor device according to claim 14, further comprising forming a MISFET including a gate insulating film formed on the semiconductor crystal layer, a gate electrode formed on the gate insulating film and an impurity diffusion layer formed in the semiconductor crystal layer.

16. The method of manufacturing a semiconductor device according to claim 15,
wherein a MISFET of a first conductivity type and a MISFET of a second conductivity type different from the first conductivity type are formed on the semiconductor crystal layers having different crystal orientations from each other, respectively.
